(19) United States
(12) Patent Application Publication
(10) Pub. No.: US 2022/0356603 A1
(43) Pub. Date: Nov. 10, 2022

(54) DYNAMIC BALANCING SEED LIFT

(71) Applicant: Linton Crystal Technologies Corp., Rochester, NY (US)

(72) Inventors: James D. Flanagan, Hilton, NY (US); Todd R. Barnum, Victor, NY (US); Jesse C. Powers, Rochester, NY (US)

(21) Appl. No.: 17/716,487

(22) Filed: Apr. 8, 2022

Related U.S. Application Data
(60) Provisional application No. 63/183,890, filed on May 4, 2021.

(51) Int. Cl. C30B 35/00; C30B 15/32; C30B 15/20

(52) U.S. Cl. CPC C30B 35/00; C30B 15/32; C30B 15/20

(57) ABSTRACT

A crystal growing system includes a rotating seed lift assembly to rotate and lift a seed crystal supported by a cable. The seed lift assembly includes a spool that rotates to wrap the cable around the spool, thus raising the cable. As the spool rotates, it moves in an axial direction to avoid displacing the cable in the axial direction. Movement of the spool and rotation of the seed lift assembly induce deviations in the center of mass of the seed lift assembly with respect to its axis of rotation, which can cause undesired movement of the cable and thus seed crystal. A dynamic counterweight system makes use of one or more sensors to detect movement of the seed lift assembly and dynamically control a motor-driven, movable counterweight to offset these deviations, thus maintaining the center of mass at or substantially in line with the axis of rotation.

### CROSS-REFERENCE TO RELATED APPLICATIONS

This application claims the benefit of and priority to U.S. Provisional Patent Application No. 63/183,890 filed May 4, 2021, which is hereby incorporated by reference herein in its entirety.

### TECHNICAL FIELD

The present disclosure relates to crystal growth equipment generally and more specifically to a dynamic balancing lift for a seed crystal.

### BACKGROUND

Large crystals, especially monocrystalline ingots, are extremely important to various fields of technology. With respect to modern electronics, monocrystalline silicon is an especially important source material used for various functions, such as wafers for integrated circuits and components of photovoltaic panels. A monocrystalline structure includes a continuous crystal lattice without grain boundaries, and can be made of a single element or of multiple elements (e.g., doped materials).

One manufacturing technique often used to create monocrystalline silicon is the Czochralski method, which involves dipping a seed crystal into a molten bath of material, then slowly pulling the seed crystal away from the molten bath while rotating the seed crystal. However, current techniques suffer from inefficiencies caused by vibration, imbalance, and other similar problems. If not performed correctly, a failure can occur and the resultant ingot may be a polycrystalline ingot, which can include grain boundaries. Since grain boundaries can be problematic for various uses, the failed ingot may have to be melted and re-grown, wasting time and energy. Since monocrystalline growth procedures often take long periods of time (e.g., on the order of tens of hours or days), any failures can have significant consequences to production efficiency.

There is a need for improved equipment for efficiently manufacturing large single crystals, such as monocrystalline silicon.

### SUMMARY

Certain aspects of the present disclosure relate to a dynamic counterweight system for crystal growing, comprising: a counterweight assembly couplable to a seed lift assembly, the seed lift assembly being rotatably coupled to a receiving chamber about an axis of rotation and supporting a seed crystal within the receiving chamber, the counterweight assembly including: a movable counterweight that is axially movable between a first position and a second position along a counterweight axis; and a counterweight driver operably coupled to the movable counterweight to induce movement of the movable counterweight along the counterweight axis in response to a control signal; one or more sensors positioned to detect movement of the seed lift assembly; and a controller operably coupled to the one or more sensors and to the counterweight driver, the controller configured to: receive one or more sensor signals from the one or more sensors; generate the control signal based on the received one or more sensor signals; and transmit the control signal to the counterweight driver, wherein the control signal, when received by the counterweight driver, induces movement of the movable counterweight to offset deviations of a center of mass of the seed lift assembly.

Certain aspects of the present disclosure relate to a crystal growing system, comprising: a furnace tank having a crucible containing a melt; a receiving chamber having a lower end coupled to the furnace tank by an isolation valve and a top end coupled to a leveling adapter by a plurality of leveling adapter posts; a seed crystal suspended within the receiving chamber by a cable along a cable centerline; a seed lift assembly rotatably coupled to the receiving chamber about an axis of rotation via the leveling adapter and having an assembly center of mass along the cable centerline, the seed lift assembly supporting the cable within the growth chamber, the seed lift assembly having a spool for raising the cable, the spool having a spool center of mass that moves with respect to the cable centerline as the cable is raised; and a dynamic counterweight system, comprising: a counterweight assembly coupled to the seed lift assembly, the counterweight assembly including: a movable counterweight that is axially movable between a first position and a second position along a counterweight axis; and a counterweight driver operably coupled to the movable counterweight to induce movement of the movable counterweight along the counterweight axis in response to a control signal; one or more sensors positioned to detect movement of the seed lift assembly; and a controller operably coupled to the one or more sensors and to the counterweight driver, the controller configured to: receive one or more sensor signals from the one or more sensors; generate the control signal based on the received one or more sensor signals; and transmit the control signal to the counterweight driver, wherein the control signal, when received by the counterweight driver, induces movement of the movable counterweight to offset deviations of the assembly center of mass from the cable centerline, and wherein at least some of the deviations of the assembly center of mass from the cable centerline are caused by the movement of the spool center of mass as the cable is raised.

Certain aspects of the present disclosure relate to a method for growing a crystal, comprising: lowering a seed crystal to a melt by a cable supported by a seed lift assembly; simultaneously rotating the seed lift assembly about an axis of rotation and raising the cable, wherein raising the cable includes raising the cable via movement of a component of the seed lift assembly, wherein movement of the component causes a center of mass of the component to be moved with respect to the axis of rotation; and dynamically offsetting a deviation of an assembly center of mass of the seed lift assembly from the axis of rotation, wherein dynamically offsetting the deviation includes: detecting movement of the seed lift assembly during rotation of the seed lift assembly via one or more sensors; generating a control signal based on the detected movement; transmitting the control signal to a counterweight driver operably coupled to a movable counterweight that is axially movable between a first position and a second position along a counterweight axis; and driving the movable counterweight by the counterweight driver in response to receiving the transmitted control signal, wherein driving the movable counterweight includes inducing movement of the movable counterweight by an amount sufficient to offset the deviation.

Additional implementations and/or aspects of the present disclosure will be apparent to those of ordinary skill in the art in view of the detailed description of various implementations, which is made with reference to the drawings, a brief description of which is provided below.

### BRIEF DESCRIPTION OF THE DRAWINGS

The specification makes reference to the following appended figures, in which use of like reference numerals in different figures is intended to illustrate like or analogous components.

FIG. 1 is a schematic diagram of a crystal growth system with a seed lift assembly and a dynamic counterweight system, according to certain aspects of the present disclosure.

FIG. 2 is a graphical projection of a front of a seed lift assembly, according to certain aspects of the present disclosure.

FIG. 3 is a partial-cutaway graphical projection of a front of a seed lift assembly, according to certain aspects of the present disclosure.

FIG. 4 is a partial-cutaway rear view of a seed lift assembly showing a dynamic counterweight assembly, according to certain aspects of the present disclosure.

FIG. 5 is a partial-cutaway, enlarged rear view of a dynamic counterweight assembly, according to certain aspects of the present disclosure.

FIG. 6 is a graphical projection of a counterweight of a dynamic counterweight assembly, according to certain aspects of the present disclosure.

FIG. 7 is a schematic top view of a seed lift assembly with the spool in a first spool position and the movable counterweight in a first counterweight position, according to certain aspects of the present disclosure.

FIG. 8 is a schematic top view of a seed lift assembly with the spool in a second spool position and the movable counterweight in a second counterweight position, according to certain aspects of the present disclosure.

FIG. 9 is a schematic rear view of a counterweight assembly, according to certain aspects of the present disclosure.

FIG. 10 is a schematic diagram of a crystal growth system having a dynamic counterweight system, according to certain aspects of the present disclosure.

FIG. 11 is a flowchart depicting a process for dynamically balancing a seed lift, according to certain aspects of the present disclosure.

### DETAILED DESCRIPTION

A crystal growing system includes a rotating seed lift assembly to rotate and lift a seed crystal supported by a cable. The seed lift assembly includes a spool that rotates to wrap the cable around the spool, thus raising the cable. As the spool rotates, it moves along its axial direction to avoid displacing the cable from the cable's axial location. Movement of the spool and rotation of the seed lift assembly induce deviations in the center of mass of the seed lift assembly with respect to its axis of rotation, which can cause undesired movement of the cable and thus seed crystal. A dynamic counterweight system makes use of one or more sensors to detect movement of the seed lift assembly and dynamically control a motor-driven, movable counterweight to offset these deviations, thus maintaining the center of mass at or substantially in line with the axis of rotation.

Certain crystal growth techniques, such as the creation of monocrystalline silicon ingots, makes use of a seed crystal suspended above a melt of material (e.g., metalloids, such as silicon) within a sealed enclosure. The seed crystal is lowered to contact the melt, then raised and rotated in a controlled fashion to permit formation of a nascent ingot of crystallized material (e.g., the growing crystal). As the seed crystal continues to be lifted away from the surface of the melt, the nascent monocrystalline ingot continues to grow until a desired length has been reached. The seed crystal and nascent ingot can be drawn vertically up into a receiving chamber above the melt.

The crystal growing process can take different amounts of times depending on the end size of the ingot. In an example, growing of a cylindrical ingot of monocrystalline silicon to approximately 5-7 meters in length may take approximately two days. Any sufficient disturbances to the system during that time can result in significant defects in the resultant ingot, which may lead to a failed ingot. A failed ingot may need to be re-melted and re-grown, which can be very expensive. Certain aspects of the present disclosure relate to improvements that permit a seed growing system to operate with reduced shaking (e.g., of the cable) and/or other disturbances.

To achieve desirable and reproducible results with high efficiency, it can be important to provide efficient and precise control of the cable used to suspend, rotate, and raise the seed crystal and nascent ingot. A seed lift assembly positioned at the top of the receiving chamber can control the rotation and lifting of the cable. The cable can exit out from the seed lift assembly at a cable port.

To control rotation, the entire seed lift assembly is rotatably coupled to the receiving chamber so that it can be rotated around an axis of rotation. The axis of rotation can be collinear with the cable exiting the seed lift assembly (e.g., collinear with the cable in the receiving chamber). A base of the seed lift assembly is rotatably coupled to the top of the receiving chamber, such as via a leveling plate, and driven (e.g., by a rotation motor) to rotate at a desired speed (e.g., on the order of ones or tens of revolutions per minute, such as 1-40 RPM).

The seed lift assembly can be coupled to the top of the receiving chamber via a leveling plate. The leveling plate can be used to establish a precisely level attachment surface for the seed lift assembly. The leveling plate can be coupled to the top of the receiving chamber via a plurality of leveling adapter posts, which can be individually adjusted to achieve a desired degree of levelness (e.g., achieve a minimum slope of the leveling adapter). For example, a set of three leveling pins may be used in some cases although any number of leveling pins may be used. In some cases, the leveling plate can support a rotation motor that controls rotation of the seed lift assembly.

The mechanisms used to raise the cable are supported by the rotating base of the seed lift assembly, and thus also rotate with respect to the receiving chamber. In some cases, the cable can be lifted by a cable winch system that includes a grooved spool or drum that collects (e.g., winds up) the cable in the groove as the spool is rotated (e.g., rotated at a speed on the order of tenths or ones of revolutions per minute). The cable winch system also axially translates the spool along its axis of rotation such that the cable does not overlap itself during the process and so the cable is not axially displaced along the spool's axis of rotation. Thus, throughout the growing process, the spool moves axially from a start position to an end position. Additionally, since additional cable is being wound around the spool as the growing process progresses, the overall combined mass of the spool and wound cable increases throughout the growing process. Thus, from the start of the growing process to the end of the growing process, the center of mass (CoM) of the spool shifts from a start location to and end location. As used herein unless otherwise indicated, the term “center of mass” as it relates to the spool refers to the center of mass of the spool and any cable wound around the spool (e.g., cable which would be axially displaced along with axial displacement of the spool).

Since the various components of the seed lift assembly have different weights, one or more static counterweights can be coupled to the base of the seed lift assembly at various locations to move the CoM of the seed lift assembly to a position aligned with a center of the cable port and/or a centerline of the cable as it exits from the cable port. In other words, a line extending axially through the center of the cable as the cable exits the cable port and passes down the receiving chamber can be known as the cable centerline. The CoM of the seed lift assembly can be positioned somewhere along this line, such as at a location above the center of the cable port.

However, because of the movement of the CoM of the spool while the cable is being raised, the CoM of the seed lift assembly would normally tend to vary away from the cable centerline during the course of the growing process. If the CoM deviates from the cable centerline (or axis of rotation of the seed lift assembly) by more than a threshold amount, the seed lift assembly can be considered as being out of balance, which can have undesirable results. If the CoM of the seed lift assembly does not sufficiently match the cable centerline and/or does not fall on the axis of rotation of the seed lift assembly, vibrations and undesirable orbits can be induced in the cable, which can negatively affect the nascent ingot. Therefore, according to certain aspects and features of the present disclosure, a dynamic counterweight system can be used to offset deviations of the seed lift assembly's CoM with respect to the cable centerline and/or axis of rotation, thus ensuring that the CoM of the seed lift assembly remains aligned with the cable centerline and/or the seed lift assembly's axis of rotation exactly or within acceptable tolerances.

As used herein, being within acceptable tolerances and/or being sufficiently in balance can include the center of mass of the seed lift assembly being within approximately 0%, 1%, 2%, 3%, 4%, 5%, 10%, 15%, 20%, 25%, 30%, 35%, 40%, 45%, 50%, 55%, 60%, 65%, 70%, 75%, 80%, 85%, 90%, 95%, 100%, 105%, 110%, 115%, 120%, 125%, 130%, 135%, 140%, 145%, 150%, 155%, 160%, 165%, 170%, 175%, 180%, 185%, 190%, 195%, 200%, 205%, 210%, 215%, 220%, 225%, 230%, 235%, 240%, 245%, and/or 250% of the diameter of the cable from the axis of rotation.

The dynamic counterweight assembly can include a movable counterweight that is movable between a first position and a second position (e.g., a first extent and a second extent). The movable counterweight can be driven by a counterweight driver. The counterweight driver can be any suitable device for receiving control signals and inducing movement of the movable counterweight. In an example, the counterweight driver can be a motor coupled to a leadscrew, which when rotated, induces sliding movement of the movable counterweight along a counterweight axis. Other counterweight drivers can be used, such as any suitable linear actuator (e.g., a pneumatic actuator, a hydraulic actuator, an electromagnetic actuator, or the like).

In some cases, a dynamic counterweight assembly can include multiple movable counterweights. In some cases when multiple movable counterweights are used, each movable counterweight can move along a counterweight axis that is non-parallel with each other movable counterweight's counterweight axis.

The counterweight driver can be driven by a controller capable of generating control signals based on sensor signals. The controller, or control system, can include one or more processors and/or other elements usable to generate the control signals. Any processor can be a general or special purpose processor or microprocessor. In some cases, the controller can include memory for storing machine-readable instructions that are executable by one or more processors to perform the functions disclosed herein, such as generation of control signals based on received sensor signals. The memory can be any suitable computer readable storage device or media, such as, for example, a random or serial access memory device, a hard drive, a solid-state drive, a flash memory device, etc. Memory can include one or more memory devices. In some cases, the controller can be implemented as or can include an application specific integrated circuit (ASIC).

In some cases, the controller is coupled to and/or incorporated within the seed lift assembly, although that need not always be the case. In some cases, the controller is separate from the seed lift assembly. In some cases, the controller is implemented using one or more components coupled to and/or incorporated within the seed lift assembly and one or more components external to and/or separated from the seed lift assembly. In some cases, however, the controller is implemented as part of the circuitry already present on the seed lift assembly (e.g., circuitry used in the operation of the spool motor).

The controller can generate control signals based on received sensor signals from one or more sensors. Any suitable sensor can be used that is capable of acquiring data associated with the movement of the seed lift assembly. In some cases, the one or more sensors include a load cell or other force-measuring sensor. In some cases, the one or more sensors include an accelerometer. In some cases, the one or more sensors include a rotational sensor or proximity sensor (e.g., magnetic proximity sensor, such as a reed sensor) for measuring the rotational position of the seed lift assembly with respect to the receiving chamber. In some cases, the one or more sensors include an optical sensor (e.g., laser reflection sensor, visual or non-visual camera, and the like). In some cases, the one or more sensors includes a rotary encoder coupled to the spool to determine a rotational position of the spool. In some cases, the one or more sensors includes a strain gauge positioned on the top pulley to detect force applied by the cable and nascent crystal from the frame of reference of the seed lift assembly.

The controller can receive one or more sensor signals and process the signal(s) to identify a corrective action to be taken. The corrective action includes controlling the counterweight driver of the dynamic counterweight assembly, via a control signal, to drive the moveable counterweight in a controlled fashion. The movable counterweight can be driven to be moved to a particular location. In some cases, the control signal can cause the moveable counterweight to be driven at a particular speed and/or for a particular duration of time.

The controller can generate the control signal based on analysis of the sensor signal(s). Analysis of the sensor signal(s) can include analyzing currently-received sensor signal(s) and optionally historical sensor signal(s) (e.g., historical sensor signals from this crystal growing procedure and/or historical sensor signals from previous crystal growing procedures). Analysis of the sensor signal(s) can be used to determine processed data. Processed data can include i) a current position of the seed lift assembly; ii) a current orientation of the seed lift assembly; iii) an estimated deviation of the current CoM of the seed lift assembly from the axis of rotation or cable centerline; iv) a projected deviation of the CoM of the seed lift assembly from the axis of rotation or cable centerline at some point in the future; or v) any combination of i-iv.

The controller can then use this processed data to generate the control signal. This generated control signal can be designed to offset a current deviation and/or a projected deviation of the CoM of the seed lift assembly from the axis of rotation or cable centerline. Thus, as used herein, the phrase “offset a deviation” and similar phrases are inclusive of i) making an adjustment to reduce a current deviation (e.g., a current distance between the CoM of the seed lift assembly and the axis of rotation or cable centerline); and ii) making an adjustment to reduce or minimize a future deviation (e.g., a potential future distance between the CoM of the seed lift assembly and the axis of rotation or cable centerline). In other words, “offsetting a deviation” can occur in some cases without the deviation ever existing.

Deviations in the CoM of the seed lift assembly from its axis of rotation or the cable centerline can occur from movement of the spool or from other sources. In some cases, the controller is configured to only account for deviations that are caused by the spool. In some cases, such as if another type of movable counterweight system is in place, the controller is configured to only account for deviations that are caused by a source other than the spool. In some cases, however, the controller is configured to try and offset any deviations.

The controller can thus effect a feedback loop designed to reduce or minimize undesirable deviations in the CoM of the seed lift assembly from its axis of rotation or the cable centerline.

The dynamic counterweight system, as described herein, can be built into a seed growing apparatus or can be retrofit onto an existing seed growing apparatus. In some cases, the dynamic counterweight system is especially suitable for retrofits because of the ease of installation (e.g., not needing to add numerous extra components, not needing to replace important components, and able to install some components in various different locations depending on need) and the ability to reuse some components for other purposes (e.g., reusing existing sensors and/or controller components).

In some cases, the dynamic counterweight assembly can be advantageously placed to help statically counter-balance other components of the seed lift assembly. In a retrofit example, installation of the dynamic counterweight assembly can include removing one or more static counterweights, optionally replacing that static counterweight(s) with one or more lighter static counterweights, as needed. In some cases, components in the dynamic counterweight assembly (e.g., the counterweight driver) can be redesigned or located farther or closer to the seed lift assembly's axis of rotation. The choice of location for components of the dynamic counterweight assembly can change the location of the dynamic counterweight assembly's center of mass with respect to the seed lift assembly's axis of rotation, which can be used to help establish static balance of the seed lift assembly. In some cases, however, the components of the dynamic counterweight assembly can be installed in other orientations, such as with the counterweight driver positioned farther from or closer to the seed lift assembly's axis of rotation.

In some cases, the dynamic counterweight can include one or more limit switches, although that need not always be the case. The limit switches can be used to confirm end-of-travel points for the movable counterweight. These limit switches are not used to identify end-of-travel points for the spool, although that need not always be the case.

The seed lift assembly can include a limit switch assembly for identifying end-of-travel points for the spool. This limit switch assembly is mechanically coupled to the spool such that rotation of the spool automatically induces movement of a contacting surface that can contact one or more limit switches of the limit switch assembly. In some cases, the mechanical coupling can include a sprocket-and-chain coupling, although that need not always be the case. A sprocket located on the spindle that drives the spool can be coupled (e.g., via a chain and gearbox) to a corresponding sprocket that drives a belt, chain, or leadscrew containing the contacting surface. Thus, rotation of the spool will necessarily include rotation of the spool's spindle, which in turn rotates the sprocket of the limit switch assembly, which induces movement of the limit switch assembly's contacting surface.

In some cases, the movable counterweight of the dynamic counterweight assembly can be a block that is slidably supported in a channel, such as by a set of wheels. The counterweight can be driven by the counterweight driver, such as a motor that drives a leadscrew that engages a nut on the counterweight, such that rotation of the leadscrew in one direction or another causes the counterweight to slide within the channel in a first axial direction or second axial direction. The counterweight driver can make use of any suitable controllable actuator. As used herein, controllable actuators can include any type of actuator that can be driven by a control signal (e.g., an electric or electronic control signal). For example, in some cases, a controllable actuator can include a hydraulic actuator (e.g., via a solenoid valve), a pneumatic actuator (e.g., via a pump), an electro-magnetic actuator, and/or other such actuators.

While described herein with reference to a winch-based lift system, certain aspects and features of the present disclosure can be used to offset movement of CoM of any movable component of a seed lift assembly, including other styles of seed lifting mechanisms.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used for illustrative purposes, but should not be used to limit the present disclosure. The elements included in the illustrations herein may not be drawn to scale.

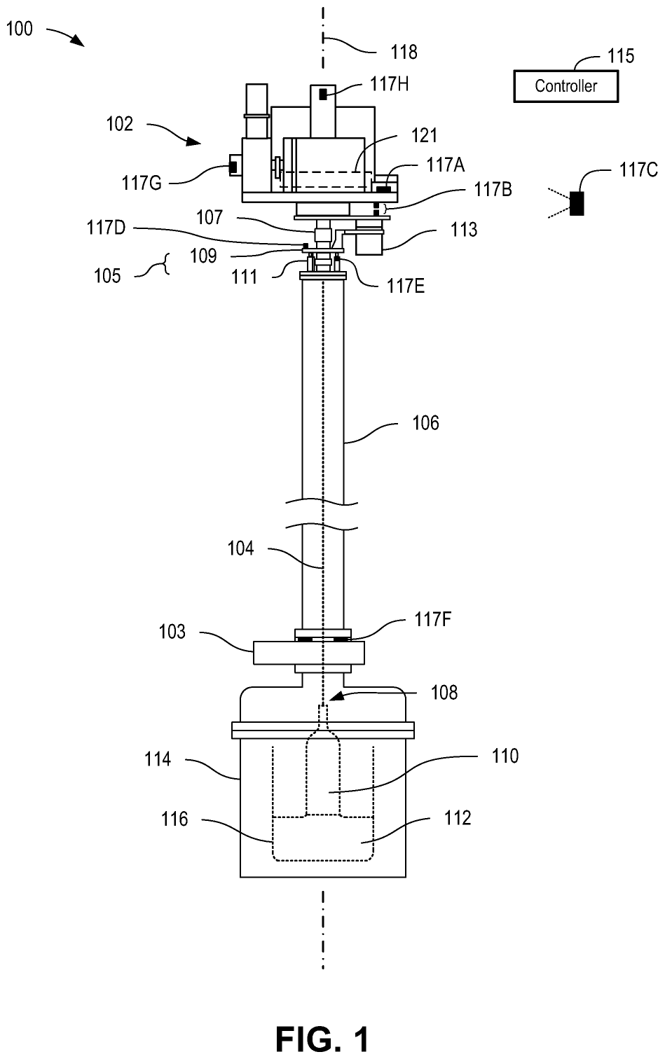

FIG. 1 is a schematic diagram of a crystal growth system 100 with a seed lift assembly 102 and a dynamic counterweight system, according to certain aspects of the present disclosure. The crystal growth system 100 can be used to grow any suitable crystals, such as monocrystalline silicon-based crystals. The crystal growth system 100 can include a furnace tank 114 containing a crucible 116 therein. The furnace tank 114 can provide heat to the crucible 116. The crucible 116 may be initially filled with solid material, which can be heated until it forms a melt 112. The crucible 116 can be controlled to rotate in a first direction.

A receiving chamber 106 can be coupled to the top of the furnace tank 114 via an isolation valve 103. The receiving chamber 106 can extend for any suitable length. A seed lift assembly 102 can be coupled to the top end of the receiving chamber 106 via a leveling adapter 105. The leveling adapter 105 can include a leveling adapter plate 109 coupled to the top end of the leveling adapter 105 by three leveling adapter pins 111. In some cases, other numbers of leveling adapter pins 111 can be used, such as one, two, or more than three. The leveling adapter pins 111 can be individually adjusted to ensure the leveling adapter plate 109 is level.

The seed lift assembly 102 can be rotatably coupled to the leveling adapter plate 109, such as via a bearing 107. Thus, the seed lift assembly 102 is rotatably coupled to the receiving chamber 106. A rotation motor 113 can control rotation of the seed lift assembly 102 about an axis of rotation 118 that passes axially through the center of the receiving chamber 106 (and axially through a centerline of the cable 104 within the receiving chamber 106).

The seed lift assembly 102 can suspend a cable 104 down through the receiving chamber 106 and into the furnace tank 114. At a distal end of the cable 104 (e.g., the end furthest from the seed lift assembly 102) is held a seed crystal 108. The seed crystal can be a small, single crystal of the same material as the melt 112.

The crystal growth system 100 is depicted between the start and end of a growing process. At the beginning of the growing process, the seed lift assembly 102 can lower the cable 104 until the seed crystal 108 contacts the melt 112. The seed lift assembly 102 can then steadily raise the seed crystal 108 (e.g., at a speed on the order of ones, tens, or hundreds of millimeters per hour, such as 0-600 mm/hr) while allowing a nascent ingot 110 to form. To obtain optimal crystal growth, the seed lift assembly 102 can rotate in a direction opposite the direction of rotation of the crucible 116 while simultaneously raising the cable 104. As the cable 104 is raised, the nascent ingot 110 is pulled out of the melt 112, allowing new material to solidify at the bottom of the nascent ingot 110 in alignment with the monocrystalline structure of the nascent ingot 110.

During the growing process, the seed lift assembly 102 will raise the cable 104, and thus the nascent ingot 110, up into the receiving chamber 106 until the growing process ends. The growing process can end when the nascent ingot 110 reaches a desired length, when the material in the crucible 116 is expended, when the seed lift assembly 102 can no longer raise the cable 104 any further, or otherwise.

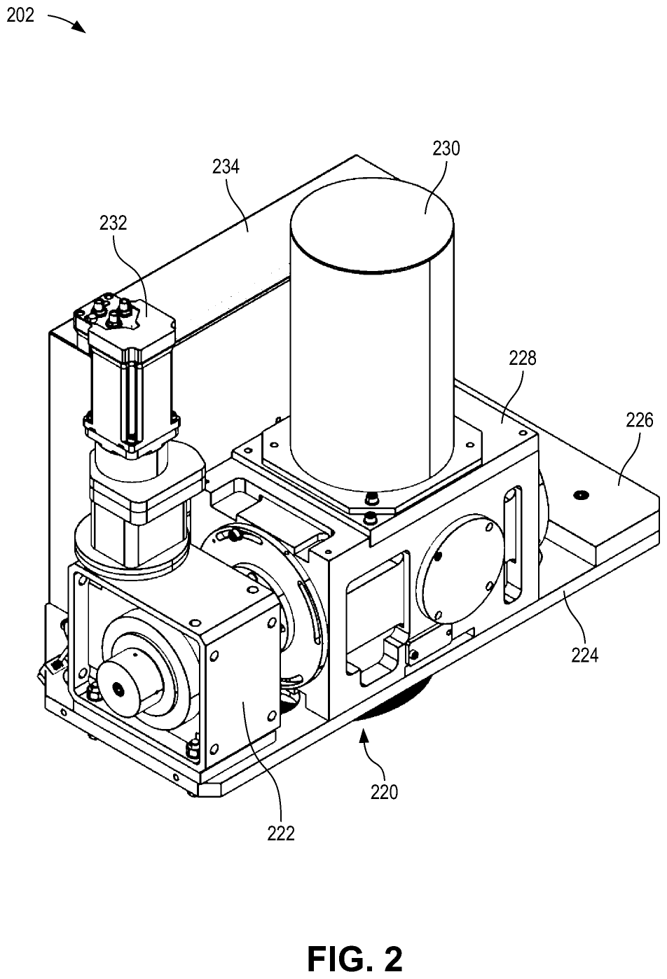

For illustrative purposes, the seed lift assembly is depicted without a covering or shroud. In some cases, a covering or shroud can surround the seed lift assembly to help maintain the desired environment within the receiving chamber 106 and furnace tank 114. The covering or shroud can keep out dust and contaminants, while permitting the gaseous environment surrounding the nascent ingot 110 to be controlled. In some cases, instead of using a shroud, a controlled environment (e.g., vacuum) can be established within the receiving chamber 106, furnace tank 114, spool housing (e.g., spool housing 228 of FIG. 2), and cable pulley assembly (e.g., cable pulley assembly 230 of FIG. 2).

The seed lift assembly 102 includes a dynamic counterweight system, which includes a controller 115, one or more sensors 117A-117H, and a dynamic counterweight assembly 121. While not normally visible in the view depicted in FIG. 1, for illustrative purposes, the dynamic counterweight assembly is depicted in dotted line. The dynamic counterweight assembly 2 can include a counterweight driver that drives a movable counterweight. The controller 115 can be located in any suitable location, and is depicted separate from the seed lift assembly 102 for illustrative purposes. In some cases, the controller 115 is located on the seed lift assembly 102. In some cases, the controller 115 is implemented by components located in disparate locations. Controller 115 can communicate with the dynamic counterweight assembly 114 and the one or more sensors 117A-117H via wired or wireless connections, which are not depicted for illustrative purposes.

During the growing process, as the seed lift assembly 102 is rotating, the controller 115 receives sensor data from the one or more sensors 117A-117H and generates a control signal that is transmitted to the dynamic counterweight assembly 121. When the control signal is received by the counterweight driver of the dynamic counterweight assembly 121, the counterweight driver induces movement of the movable counterweight to help maintain the center of mass of the seed lift assembly 102 along the axis of rotation 118 (e.g., to reduce any existing deviations of the center of mass from the axis of rotation 118 or to avoid future deviations of the center of mass from the axis of rotation 118).

The one or more sensors 117A-117H can include any suitable sensor, such as those described herein. The sensors 117A-117H depicted in FIG. 1 are examples indicative of certain useful locations for placement of a sensor, although sensors could be placed in any suitable location. A dynamic counterweight system can make use of any combination of one or more sensors 117A-117H and/or other sensors. Sensor 117A can be an accelerometer coupled to the base plate of the seed lift assembly 102 to measure acceleration of the seed lift assembly 102. Sensor 117B can be a proximity sensor coupled to or positioned adjacent the rotational motor 113 to measure rotational position of the seed lift assembly 102. For example, sensor 117B can include a magnetic source coupled to the base plate of the seed lift assembly 102 and a magnetic sensor (e.g., reed sensor) coupled to the rotational motor 113 to indicate whenever the seed lift assembly 102 rotates to a known rotational position. Sensor 117C can be a visual inspection camera positioned (e.g., at a location spaced apart from the other components of the crystal growth system 100) and oriented to visually capture the seed lift assembly 102 and/or receiving chamber 106. In some cases, sensor 117C can be positioned within the receiving chamber 106 or furnace 114 to visually capture the cable 104, seed crystal 108, and/or nascent ingot 110. Sensor 117D can be an accelerometer coupled to the leveling adapter plate 109 to measure movement of the seed lift assembly 102 via movement of the leveling adapter plate 109. As the seed lift assembly 102 moves, especially if a deviation exists between the CoM and the axis of rotation 118, the leveling adapter plate 109 will move accordingly. Sensor 117E can be a load cell positioned at one of the leveling adapter pins 111 to measure the force applied by the leveling adapter plate 109 and seed lift assembly 102 on that leveling adapter pin 111. Especially if the seed lift assembly 102 is out of balance (e.g., a deviation exists between the CoM and the axis of rotation 118), the force measured at sensor 117E will change as the seed lift assembly 102 rotates. Sensor 117F can be a load cell positioned between the receiving chamber 106 and the isolation valve 103 to measure force applied to the furnace tank 114 via the receiving chamber 106. Especially if the seed lift assembly 102 is out of balance, the force measured at sensor 117F will change as the seed lift assembly 102 rotates. Sensor 117G can be a rotary encoder mechanically coupled to the spool upon which the cable 104 is wound to measure the rotational position (including number of rotations) of the spool. Rotational position of the spool can be used to effectively determine the CoM of the spool. Sensor 117H can be a strain gauge sensor supporting a pulley through which the cable 104 passes before exiting the seed lift apparatus 102. Sensor 117H can measure the weight on the cable 104 from the frame of reference of the seed lift apparatus 102 (e.g., the force applied by the cable 104, seed crystal 108, and nascent ingot 110 on the seed lift apparatus 102). While sensors 117A-117H depict useful locations and types of sensors, any suitable type of sensor can be used at any suitable location.

FIG. 2 is a graphical projection of a front of a seed lift assembly 202, according to certain aspects of the present disclosure. The seed lift assembly 202 can be any suitable seed lift assembly, such as seed lift assembly 102 of FIG. 1. The seed lift assembly 202 can include a base plate 224 upon which various components can be mounted. The cable can exit out a cable port 220 on the underside of the base plate 224.

The seed lift assembly 202 can include a spool located within a spool housing 228. The cable can wrap around the spool, allowing the spool to control lowering and raising of the cable via rotation. The cable can unwrap from the spool and pass upwards and around a pulley within the cable pulley assembly 230 before passing back downwards and out the cable port 220. The pulley within the cable pulley assembly 230 can facilitate maintaining the cable at the center of the cable port 220.

Rotation of the spool can be controlled by a spool motor 232. The spool motor 232 can drive a gearbox 222 that in turn drives a spool spindle that drives rotation of the spool. For example, the spool spindle can be rotationally fixed to the spool such that rotation of the spool spindle induces corresponding rotation of the spool.

An electronics enclosure 234 can be located on the base plate 224 to house electronics used to control and monitor the components of the seed lift assembly 202, such as a controller of a dynamic counterweight system (e.g., controller 115 of FIG. 1). As described herein, it can be useful to maintain a center of balance of the seed lift assembly 202 at a center of the cable port 220. Thus, because of the presence of heavy equipment (e.g., the spool motor 232, spool gearbox 222, and portions of the spool housing 228) on one side of the base plate 224, one or more static counterweights 226 can be located on the opposite side of the base plate 224.

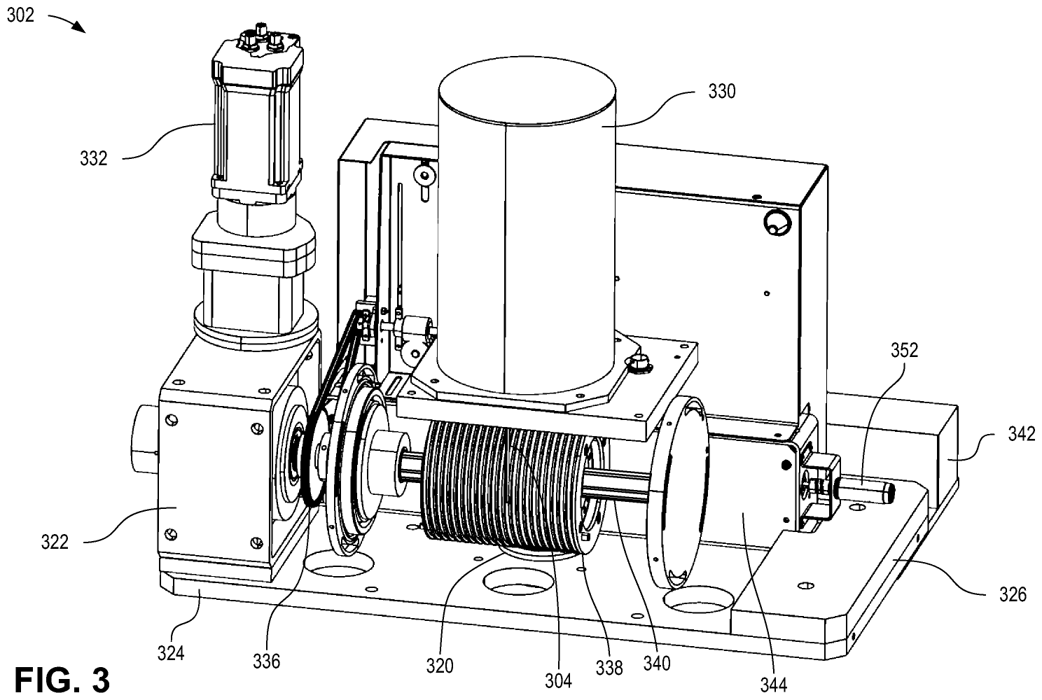

FIG. 3 is a partial-cutaway graphical projection of a front of a seed lift assembly 302, according to certain aspects of the present disclosure. The seed lift assembly 302 can be any suitable seed lift assembly, such as seed lift assembly 102 of FIG. 1. As depicted in FIG. 3, some components, such as the spool housing, are not depicted for illustrative purposes.

The spool 338 is driven by the spool spindle 340, which is driven by the spool gearbox 322, which is in turn driven by the spool motor 332. As the spool spindle 340 turns to rotate the spool 338, the spool spindle can also rotate a spool sprocket 336. The spool sprocket can mechanically couple the spool to limit switch assembly such that axial translation of the spool 338 along the spool spindle 340 induces corresponding movement of a contacting surface of the limit switch assembly towards a limit switch.

A cable 304 is depicted exiting a groove of the spool 338 and entering the cable pulley assembly 330 before being directed downwards and out the cable port 320.

Additionally, the seed lift apparatus 302 of FIG. 3 includes a base plate 324 having a first static counterweight 326 and a second static counterweight 342. The first and second static counterweights 326, 342 can act as a stationary counterbalance to the stationary components of the seed lift apparatus 302. As the center of balance of the spool 338 is moved in a first direction (e.g., from right to left as depicted in FIG. 3), a movable counterweight of the dynamic counterweight assembly 344 can be driven (e.g., by a counterweight driver, such as motor 352) appropriately (e.g., in an opposite direction, such as form left to right as depicted in FIG. 3) to counterbalance the spool 338.

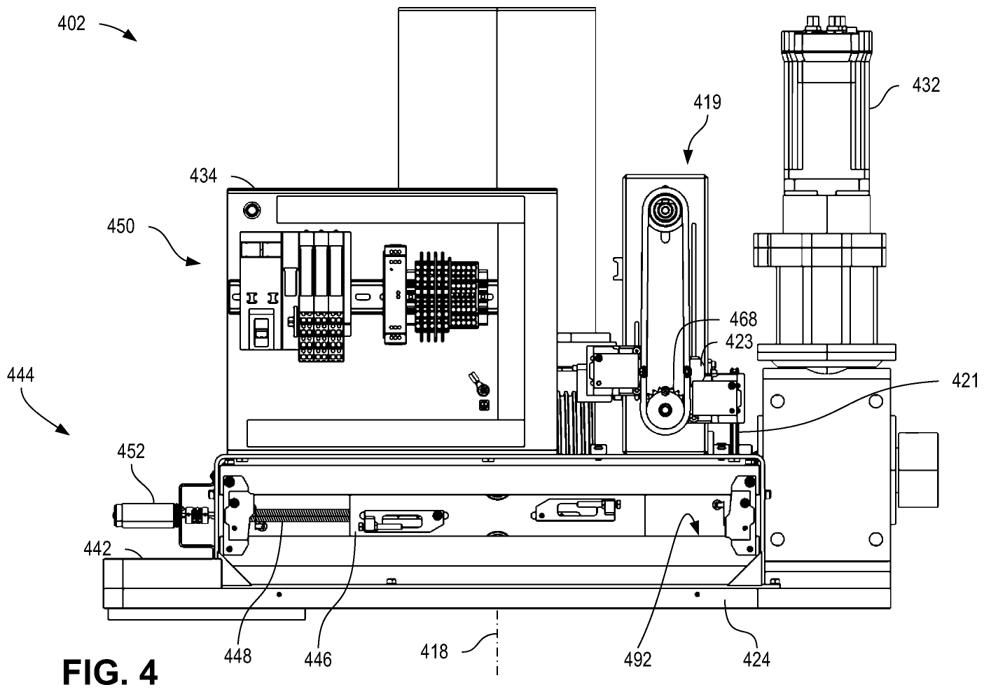

FIG. 4 is a partial-cutaway rear view of a seed lift assembly 402 showing the dynamic counterweight assembly 444, according to certain aspects of the present disclosure. The seed lift assembly 402 can be any suitable seed lift assembly, such as seed lift assembly 102 of FIG. 1. Coverings of the housings of the electronics enclosure 434 and dynamic counterweight assembly 444 are not depicted for illustrative purposes.

Electronics assembly 434 can include electronics 450 used to control and/or monitor the seed lift apparatus 402. In some cases, these electronics 450 can include the controller (e.g., controller 115 of FIG. 1) or part of the controller used to generate the control signals to control the dynamic counterweight assembly 444. In some cases, the dynamic counterweight assembly 444 can be located underneath the electronics assembly 434. The dynamic counterweight assembly 444 can be coupled directly to the base plate 424, although that need not always be the case. However, it can be desirable to maintain the center of mass of the counterweight 446 closer to the base plate 424 rather than further spaced apart from the base plate 424.

The dynamic counterweight assembly 444 can include a movable counterweight 446 driven by a leadscrew 448. The counterweight 446 can be driven to move axially (e.g., axially in a direction of the axis of the leadscrew 448) by a counterweight driver, such as motor 452. The counterweight 446 can be slidably mounted within a channel 492. As disclosed in further detail herein, sensor data received by a controller can be processed to generate a control signal that can be used to control motor 452 to cause the leadscrew 448 to rotate, thus inducing axial movement of the counterweight 446.

The limit switch assembly 419 is depicted, having a sprocket 468 that is driven, via a gearbox, by a linkage 421 (e.g., chain) that is coupled to the spool sprocket. Thus, as the spool is rotated, the sprocket 468 is thereby rotated, causing a contacting surface 423 to move towards (or away from) a limit switch.

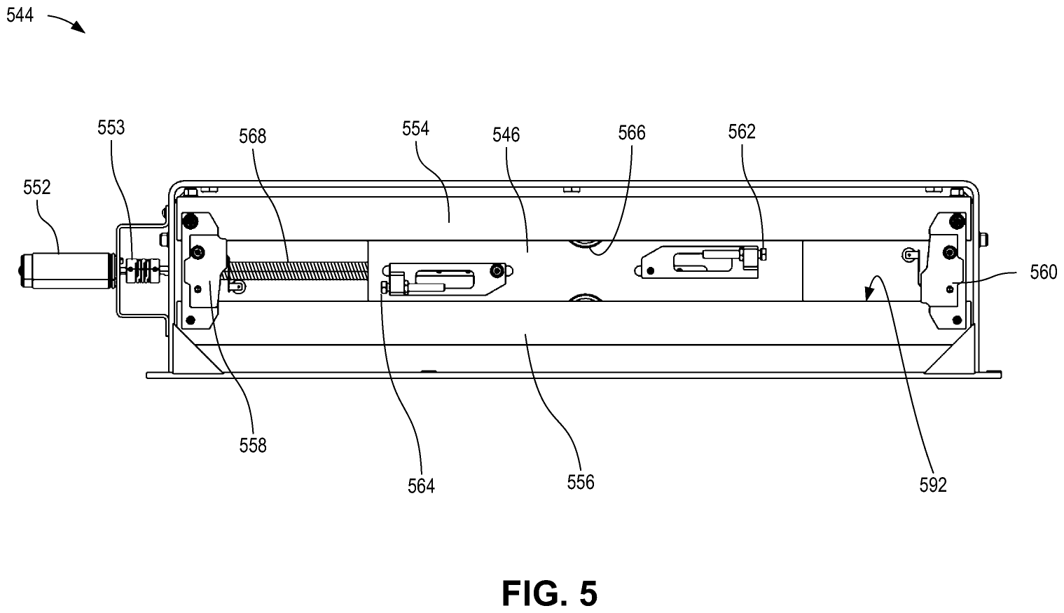

FIG. 5 is a partial-cutaway, enlarged rear view of a dynamic counterweight assembly 544, according to certain aspects of the present disclosure. The dynamic counterweight assembly 544 can be any suitable counterweight assembly, such as dynamic counterweight assembly 444 of FIG. 4.

The dynamic counterweight assembly 544 can include a counterweight 546 located (e.g., slidably located) within a channel 592 of the housing of the dynamic counterweight assembly 544. While use of a channel 592 is depicted in FIG. 5, other techniques can be used to restrict undesired movement (e.g., non-axial movement) of the counterweight 546, such as stabilizing bars, carriages, and the like.

The channel 592 can be formed from various walls of the housing of the counterweight assembly 544. In some cases, at least one wall (e.g., the rear wall, or the wall coplanar with the page in FIG. 5 and facing out of the page) can include a split or opening, such as an opening between an upper wall portion 554 and a lower wall portion 556. Such a split wall can facilitate access to the counterweight 546, if needed.

Additionally, such a split wall can permit endstops 562, 564 to be coupled to the counterweight 546 and extend past the upper wall portion 554 and lower wall portion 556. Each of the endstops 562, 564 can include an adjustable stop coupled to the counterweight 546 via a block. Each endstop 562, 564 can engage respective limit switches 558, 560 adjacent opposite ends of the channel 592. In some cases, limit switches 558, 560 can be positioned elsewhere, such as within the channel 592, in which cases the limit switches 558, 560 may be engaged by the counterweight 546 itself. However, by using the endstops 562, 564 and limit switches 558, 560 depicted in FIG. 5, the extent of travel of the counterweight 546 can be controlled by adjusting the position of the desired endstop 562, 564 (e.g., via adjustment of the adjustable stop within the block and/or adjustment of the block on the counterweight 546). While depicted with limit switches 558, 560 and end stops 562, 564 in FIG. 5, in some cases, a dynamic counterweight assembly 544 may be implemented without any limit switches 558, 560 and end stops 562, 564.

To facilitate smooth slidable motion, the counterweight 546 can include one or more wheels 566. Wheels 566 can engage various walls of the channel 592, such as the upper wall portion 554 and lower wall portion 556. In some cases, other friction-reducing techniques can be used in addition to or instead of wheels 566.

Motor 552 can be coupled to the lead screw 568 via a coupling 553 (e.g., an axial shaft coupling).

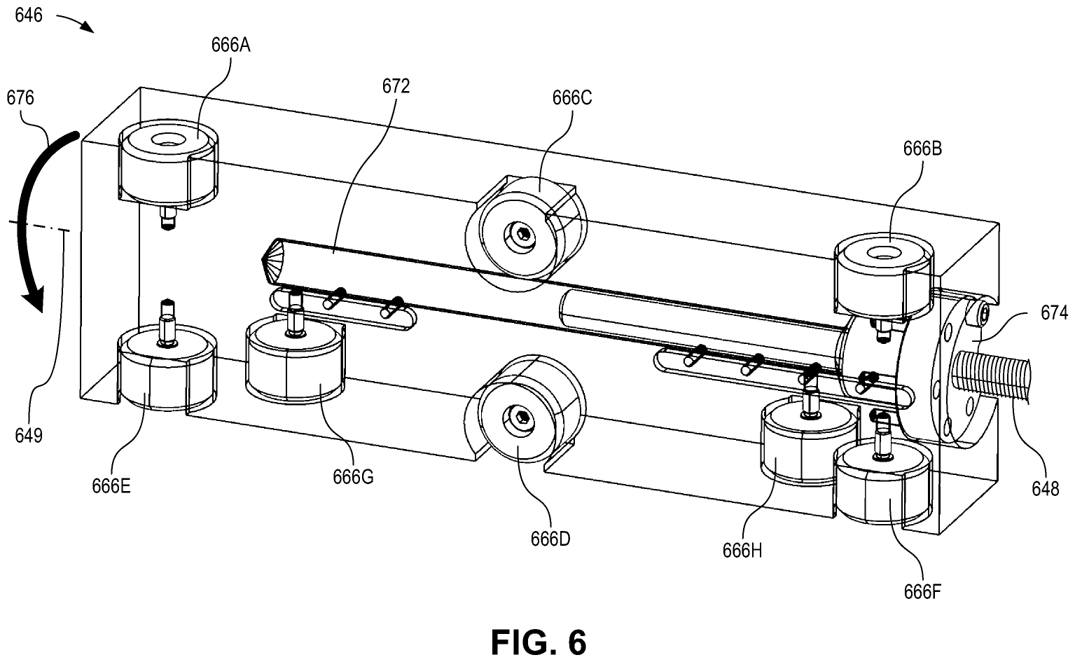

FIG. 6 is a graphical projection of the front side of a counterweight 646 of a dynamic counterweight assembly, according to certain aspects of the present disclosure. The counterweight 646 can be any suitable counterweight, such as counterweight 446 of FIG. 4. For illustrative purposes, counterweight 446 is depicted as transparent.

Counterweight 646 can be of any suitable shape, although in some cases a rectangular shape is used. The counterweight 646 can include a number of wheels 666A, 666B, 666C, 666D, 666E, 666F, 666G, 666H. Any number can be used, but in some cases eight wheels are used. Wheels 666A, 666B can be positioned on a top rear side at opposite ends of the counterweight 646 from one another. Wheels 666A, 666B can engage the upper wall portion of the channel (e.g., upper wall portion 554 of FIG. 5). Corresponding wheels 666E, 666F can be positioned on a bottom rear side at opposite ends of the counterweight 646 from one another. Wheels 666E, 666F can engage the lower wall portion of the channel (e.g., lower wall portion 556 of FIG. 5). Wheels 666C, 666D can be positioned on respective top and bottom sides of the counterweight 646, to engage corresponding surfaces in the channel.

To drive the counterweight 646, leadscrew 648 can interact with nut 674. Nut 674 can be rotationally fixed to the counterweight 646. A cavity 672 within the counterweight can extend through some or all of the counterweight 646 and have a diameter greater than the diameter of the leadscrew 648, thus permitting the counterweight 646 to move up (e.g., proximally) along the leadscrew 648. As the leadscrew 648 is rotated by the counterweight driver (e.g., motor 552 of FIG. 5), the nut 674 is held rotationally fixed to the counterweight 646, which is in turn held substantially rotationally fixed with respect to the channel. Thus, rotation of the leadscrew 648 causes the nut 674 to move up (e.g., proximally) or down (e.g., distally) along the leadscrew 648.

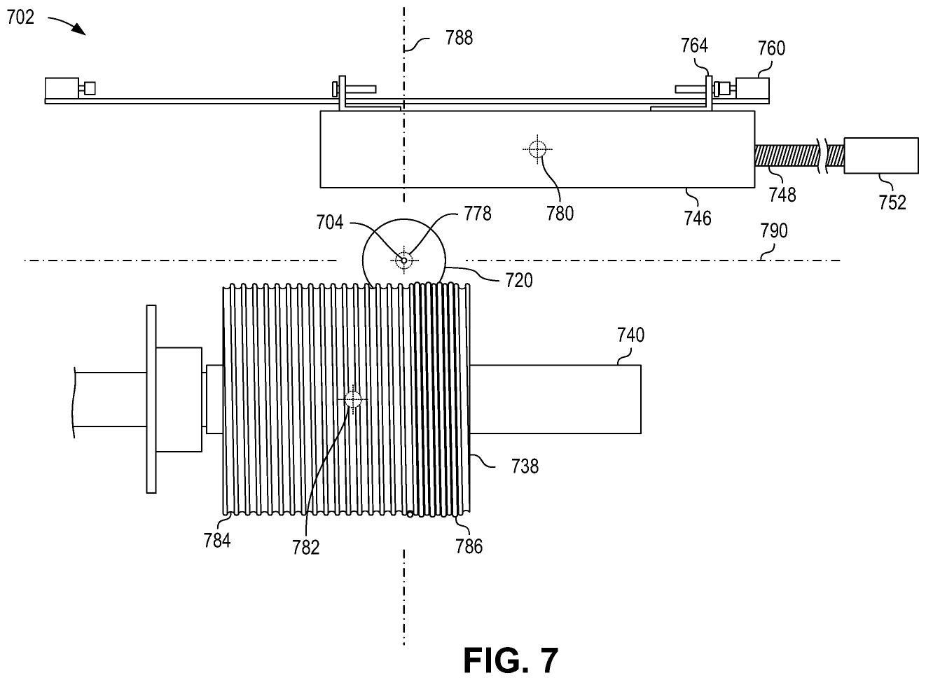

FIG. 7 is a schematic top view of a seed lift assembly 702 with the spool 738 in a first spool position and the movable counterweight 746 in a first counterweight position, according to certain aspects of the present disclosure. The seed lift assembly 702 can be any suitable seed lift assembly, such as seed lift assembly 102 of FIG. 1. In some cases, the first spool position and first counterweight position can correspond with a start spool position and start counterweight position at the beginning of a crystal growing process (e.g., at the start of raising the cable from the melt). In such a start position, the entire seed lift assembly 702 may be in balance, although that need not always be the case. A cable 704 can enter the seed lift assembly 702 via cable port 720.

A lateral centerline 788 (or lateral plane) of the seed lift assembly 702 can be defined as a line (or plane) extending through the center of the cable port 720 (e.g., and through the center of mass 778 of the seed lift assembly 702) and perpendicular to the axis of the spool spindle 740. The lateral centerline 788 (or lateral plane) can separate the seed lift assembly 702 into a “left” side and a “right” side as depicted in FIG. 7.

A longitudinal centerline 790 (or longitudinal plane) of the seed lift assembly 702 can be defined as a line (or plane) extending through the center of the cable port 720 (e.g., and through the center of mass 778 of the seed lift assembly 702) and parallel to the axis of the spool spindle 740. The longitudinal centerline 790 (or longitudinal plane) can separate the seed lift assembly 702 into a “top” side and a “bottom” side as depicted in FIG. 7.

In the first spool position, spool 738 is positioned proximally along spool spindle 740. The spool 738 includes a few rotations of wound cable 786 in its grooves 784. The spool center of mass 782 is depicted, and rests to the left of the lateral centerline 788 and to the bottom of the longitudinal centerline 790.

In the first counterweight position, counterweight 746 is located proximally along the leadscrew 748. In some cases, in the first counterweight position, a first endstop 764 can engage a first limit switch 760, although this need not always be the case. The counterweight center of mass 780 is depicted, and rests to the right of the lateral centerline 788, or on an opposite side of the lateral centerline 788 from the spool center of mass 782. The counterweight center of mass 780 rests to the top of the longitudinal centerline 790, or on an opposite side of the longitudinal centerline 790 from the spool center of mass 782. For illustrative purposes, the counterweight center of mass 780 is depicted as on an opposite side of the lateral centerline 788 from the spool center of mass 782, although this need not always be the case. In some cases, the counterweight 746 may be positioned such that it does not cross the lateral centerline 788 during use.

As the spool 738 is rotated to wind up additional cable 704, it will move distally along the spool spindle 740 (e.g., from left to right as seen in FIG. 7). The spool center of mass 782 will move towards the lateral centerline 788, and in some cases, move past the lateral centerline 788. As the spool 738 rotates, axial movement of the spool 738 can cause deviation in the center of mass 778 of the seed lift assembly 702 from the axis of rotation 704. This deviation can be detected by a controller (e.g., controller 115 of FIG. 1) via sensor data from one or more sensors (e.g., sensors 117A-117H). The controller can then generate a control signal to drive motor 752, which in turn rotates the lead screw 748 to drive the counterweight 746 to move axially in a direction opposite the spool 738 (e.g., the counterweight 746 can move from right to left as seen in FIG. 7). The counterweight center of mass 780 will move towards the lateral centerline 788, and in some cases, move past the lateral centerline 788. In some cases, when the spool center of mass 782 reaches the lateral centerline 788, the counterweight center of mass 780 will also reach the lateral centerline 788 although that need not always be the case. Movement of the counterweight 746 can help reduce the deviation and further stop future deviations from occurring.

Thus, as the spool center of mass 782 moves with respect to the center of the cable port 720, the counterweight center of mass 780 can be driven, based on sensor data, in a corresponding, opposite direction to maintain the center of mass 778 of the seed lift assembly 702 in the same location (e.g., at or above the center of the cable port 720 and/or along an axis of rotation of the seed lift assembly 702). Additionally, the counterweight center of mass 780 can be driven, based on sensor data, in a fashion suitable to account for other sources of center of mass 778 deviation.

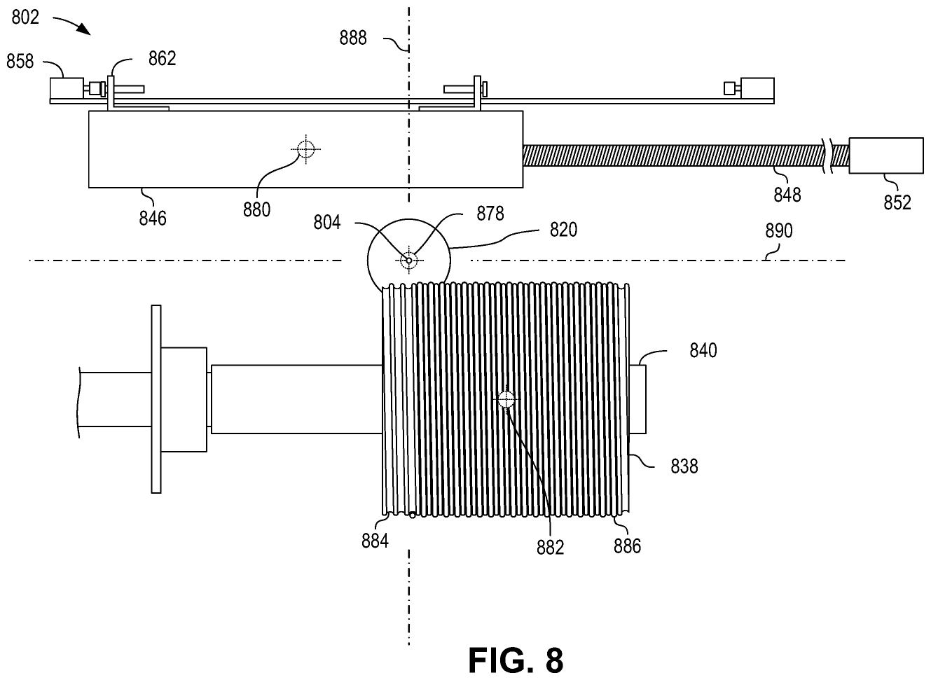

FIG. 8 is a schematic top view of a seed lift assembly 802 with the spool 838 in a second spool position and the movable counterweight 846 in a second counterweight position, according to certain aspects of the present disclosure. The seed lift assembly 802 can be any suitable seed lift assembly, such as seed lift assembly 102 of FIG. 1. In some cases, the second spool position and second counterweight position can correspond with an end spool position and end counterweight position at the end of a crystal growing process (e.g., after the cable has been raised to its highest set point), although this need not always be the case. A cable 804 can enter the seed lift assembly 802 via cable port 820.

A lateral centerline 888 (or lateral plane) of the seed lift assembly 802 can be defined as a line (or plane) extending through the center of the cable port 820 (e.g., and through the center of mass 878 of the seed lift assembly 802) and perpendicular to the axis of the spool spindle 840. The lateral centerline 888 (or lateral plane) can separate the seed lift assembly 802 into a “left” side and a “right” side as depicted in FIG. 8.

A longitudinal centerline 890 (or longitudinal plane) of the seed lift assembly 802 can be defined as a line (or plane) extending through the center of the cable port 820 (e.g., and through the center of mass 878 of the seed lift assembly 802) and parallel to the axis of the spool spindle 840. The longitudinal centerline 890 (or longitudinal plane) can separate the seed lift assembly 802 into a “top” side and a “bottom” side as depicted in FIG. 8.

In the second spool position, spool 838 is positioned distally along spool spindle 840. The spool 838 includes numerous rotations of wound cable 886 in its grooves 884. The spool center of mass 882 is depicted, and rests to the right of the lateral centerline 888 and to the bottom of the longitudinal centerline 890.

In the second counterweight position, counterweight 846 is located distally along the leadscrew 848. In some cases, in the second counterweight position, a second endstop 862 can engage a second limit switch 858. The counterweight center of mass 880 is depicted, and rests to the left of the lateral centerline 888, or on an opposite side of the lateral centerline 888 from the spool center of mass 882. The counterweight center of mass 880 rests to the top of the longitudinal centerline 890, or on an opposite side of the longitudinal centerline 890 from the spool center of mass 882. For illustrative purposes, the counterweight center of mass 880 is depicted as on an opposite side of the lateral centerline 888 from the spool center of mass 882, although this need not always be the case. In some cases, the counterweight 846 may be positioned such that it does not cross the lateral centerline 888 during use.

As the spool 838 is rotated to unwind the wound cable 886, it will move proximally along the spool spindle 840 (e.g., from right to left as seen in FIG. 8). The spool center of mass 882 will move towards the lateral centerline 888, and in some cases, move past the lateral centerline 888. As the spool 838 rotates, axial movement of the spool 838 can cause deviation in the center of mass 878 of the seed lift assembly 802 from the axis of rotation 804. This deviation can be detected by a controller (e.g., controller 115 of FIG. 1) via sensor data from one or more sensors (e.g., sensors 117A-117H). The controller can then generate a control signal to drive motor 852, which in turn rotates the lead screw 848 to drive the counterweight 846 to move axially in a direction opposite the spool 838 (e.g., the counterweight 846 can move from left to right as seen in FIG. 8). The counterweight center of mass 880 will move towards the lateral centerline 888, and in some cases, move past the lateral centerline 888. In some cases, when the spool center of mass 882 reaches the lateral centerline 888, the counterweight center of mass 880 will also reach the lateral centerline 888, although that need not always be the case. Movement of the counterweight 846 can help reduce the deviation and further stop future deviations from occurring.

Thus, as the spool center of mass 882 moves with respect to the center of the cable port 820, the counterweight center of mass 880 can be driven, based on sensor data, in a corresponding, opposite direction to maintain the center of mass 878 of the seed lift assembly 802 in the same location (e.g., at or above the center of the cable port 820 and/or along an axis of rotation of the seed lift assembly 802). Additionally, the counterweight center of mass 880 can be driven, based on sensor data, in a fashion suitable to account for other sources of center of mass 878 deviation.

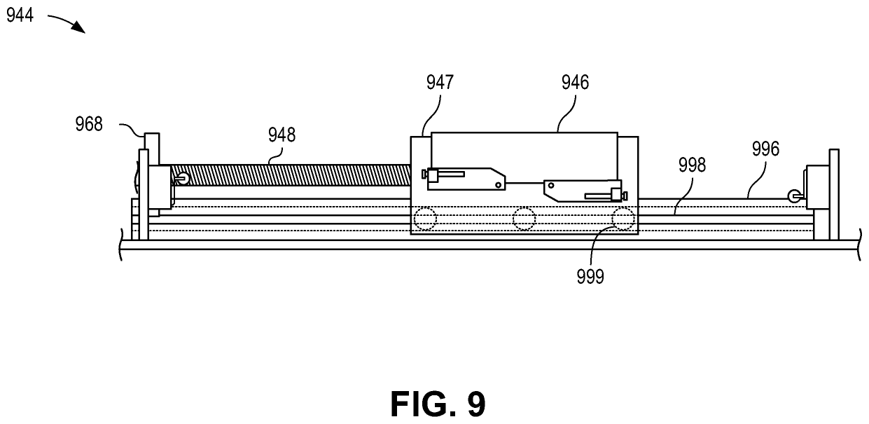

FIG. 9 is a schematic rear view of a dynamic counterweight assembly 944, according to certain aspects of the present disclosure. Dynamic counterweight assembly 944 is an alternate style of counterweight assembly that can be used in any suitable seed lift assembly, such as seed lift assembly 102 of FIG. 1.

Dynamic counterweight assembly 944 can be similar to other dynamic counterweight assemblies as disclosed herein, but the counterweight 946 can be coupled to a carriage 947 travelling on a linear rail 996. The counterweight 946, carriage 947, and rail 996 can act as counterweights to components on an opposite side of the seed lift assembly, with the counterweight 946 and carriage 947 movable to compensate for movement of the spool and otherwise correct deviations in the center of mass of the seed lift assembly.

Leadscrew 948 can be coupled to carriage 947 such that rotation of the leadscrew 948 by a counterweight driver (e.g., motor 552 of FIG. 5) will cause the carriage 947 to move axially along the rail 996. Rollers 999 of the carriage 947 can fit within a track 998 of the rail 996 to maintain the carriage 947 sliding along rail 996 with low friction. In some cases, rollers 999 can be in the form of wheels or bearings. In some cases, the linear rail 996 can be an extrusion with a “T”-shaped track 998.

A counterweight 946 can be coupled to carriage 947. In some cases, counterweight 946 can be coupled to the carriage 947 in only a single location, although that need not always be the case. In some cases, the counterweight 946 can be coupled to the carriage 947 at multiple axial positions (e.g., positions from left to right as seen in FIG. 9). In such cases, the counterweight 946 can be adjusted axially with respect to the carriage 947 to fine-tune the location of the combined center of weight of the counterweight 946 and carriage 947, such as with respect to the center of weight of the spool.

In some cases, rail 996 can be replaced with two or more rails. In some cases, axial movement of the carriage 947 can be driven using an alternate linear actuator instead of a leadscrew 948.

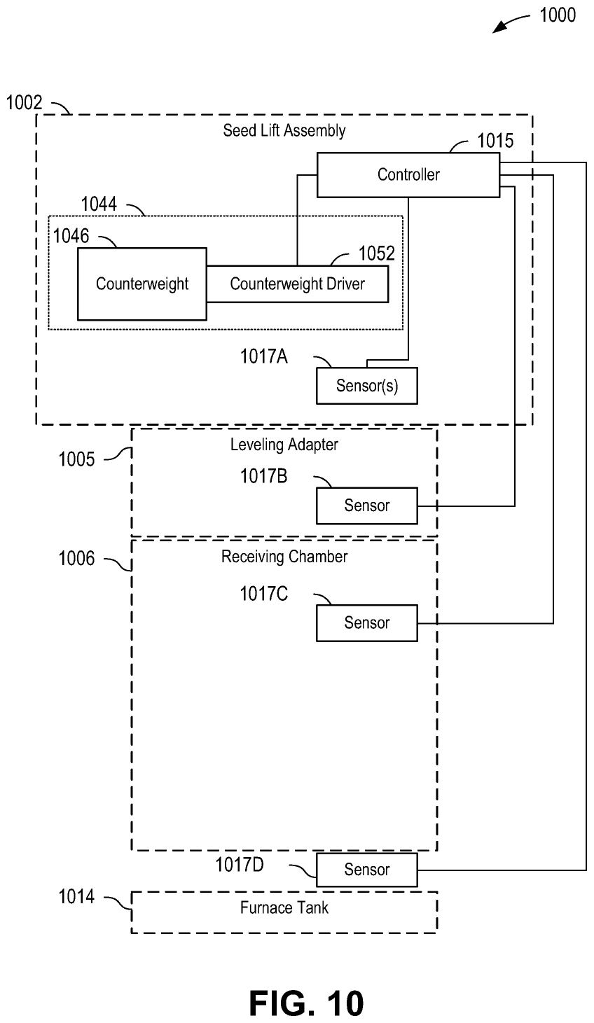

FIG. 10 is a schematic diagram of a crystal growth system 1000 having a dynamic counterweight system, according to certain aspects of the present disclosure. Crystal growth system 1000 can be any suitable crystal growth system, such as crystal growth system 100 of FIG. 1. The crystal growth system 1000 can include a seed lift assembly 1002 rotatably coupled to a receiving chamber 1006 via a leveling adapter 1005. The receiving chamber 1006 can be coupled to a furnace tank 1014.

The dynamic counterweight system can include a dynamic counterweight assembly 1044, which includes a counterweight 1046 driven by a counterweight driver 1052; a controller 1015; and one or more sensors 1017A-1017D. The controller 1015 is depicted as being housed within the seed lift assembly 1002, although that need not always be the case. The controller 1015 is communicatively coupled to the counterweight driver 1052 and each of the one or more sensors 1017A-1017D. The controller 1015 receives sensor data from the one or more sensors 1017A-1017D and processes the sensor data to generate a control signal, which is then supplied to the counterweight driver 1052 to drive the counterweight 1046 to dynamically bring the seed lift assembly 1002 towards balance (e.g., the center of mass of the seed lift assembly 1002 have no or substantially no deviation from the axis of rotation of the seed lift assembly 1002) or keep the seed lift assembly 1002 in balance.

Sensor 1017A can be an accelerometer coupled to the seed lift assembly 1002, such as at the base plate of the seed lift assembly 1002, to measure acceleration of the seed lift assembly 1002. Sensor 1017B can be an accelerometer or load sensor coupled to or otherwise positioned at the leveling adapter 1005 to measure movement of the seed lift assembly 1002 via measurements of movement of the leveling adapter plate of the leveling adapter or measurements of force applied through one or more leveling adapter pins of the leveling adapter. As the seed lift assembly 1002 moves, especially when it is not in balance, the leveling adapter plate will move accordingly and the amount of force being applied through each leveling adapter pin will vary with the rotational position of the seed lift assembly 1002. Sensor 1017C can be an accelerometer positioned on the receiving chamber 1006 to measure movement of the receiving chamber. As the seed lift assembly 1002 moves, especially when it is not in balance, the receiving chamber 1006 will move accordingly. Sensor 1017D can be a load cell positioned between the receiving chamber 1006 and the furnace tank 1014 (e.g., between the receiving chamber 1006 and an isolation valve that couples the receiving chamber 1006 to the furnace tank 1014) to measure force applied to the furnace tank 1014 via the receiving chamber 1006. Especially if the seed lift assembly 1002 is out of balance, the force measured at sensor 1017D will change as the seed lift assembly 1002 rotates. Sensors 1017B-1017D can be considered to be fixedly positioned with respect to the receiving chamber. For example, if each of sensors 1017B-1017D was an accelerometer, it would be able to detect acceleration of the receiving chamber.

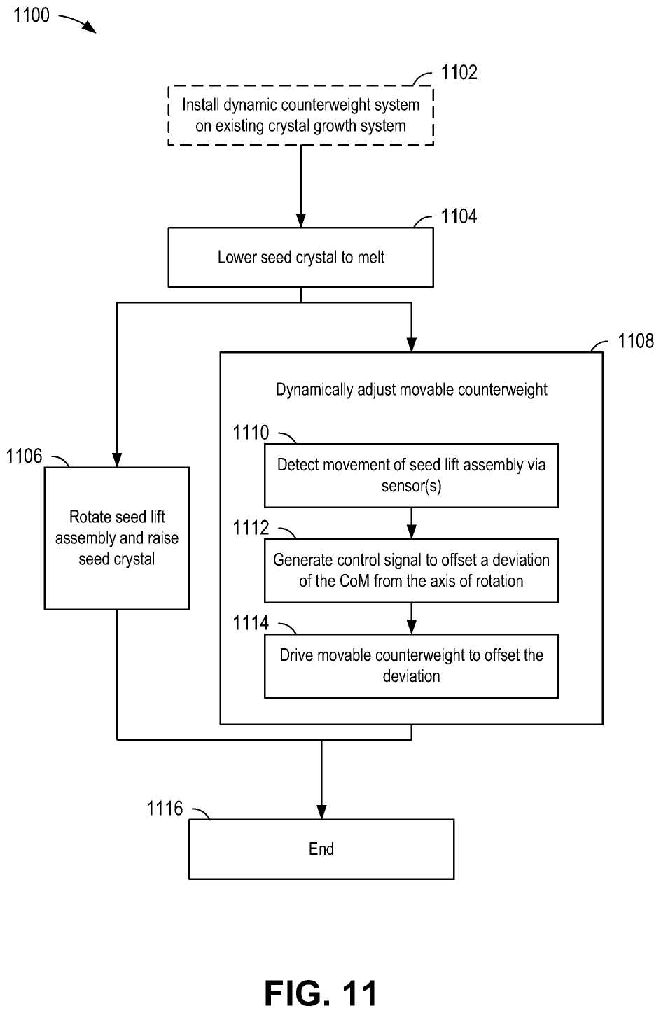

FIG. 11 is a flowchart depicting a process 1100 for dynamically balancing a seed lift, according to certain aspects of the present disclosure. Process 1100 can be performed by any suitable crystal growth system, such as crystal growth system 100 of FIG. 1.

In some cases, process 1100 can optionally begin at block 1102 by installing a dynamic counterweight system onto an existing crystal growth system. Thus, at block 1102, an existing crystal growth system can be retrofit to perform dynamic counterweight balancing.

At block 1104, a seed crystal is lowered to a melt. The seed crystal is attached to a cable or similar flexible support that is itself supported by a seed lift assembly. The seed crystal can be lowered to contact the melt and begin seeding crystal formation.

At block 1106, the seed lift assembly is rotated, and the seed crystal is raised. Rotating the seed lift assembly includes inducing the seed crystal to rotate with respect to the melt. In some cases, rotating the seed lift assembly occurs while a crucible containing the melt is rotated in an opposite direction. Raising the seed crystal can include winding the cable onto a spool. Winding the cable onto the spool includes axially displacing the spool, and thus axially displacing the spool's center of mass, with respect to the center of mass of the seed lift assembly.

At block 1108, a movable counterweight is dynamically adjusted. This dynamic adjustment of the movable counterweight at block 1108 occurs simultaneously with the rotation of the seed lift assembly at block 1106. Dynamic adjustment of the movable counterweight at block 1108 can include detecting movement of the seed lift assembly at block 1110. Movement of the seed lift assembly detected at block 1110 can be detected by one or more sensors. In some cases, detection of movement of the seed lift involves detecting changes in acceleration or changes in force, of one or more components of the crystal growth system, that have been induced due to the rotation of the seed lift assembly while the seed lift assembly is not perfectly in balance.

After the movement of the seed lift assembly is detected at block 1110, a control signal can be generated at block 1112. The control signal can be generated based on the sensor data received from the one or more sensors of block 1110. The control signal can be generated such that it would bring the seed lift assembly towards balance (e.g., the center of mass of the seed lift assembly have no or substantially no deviation from the axis of rotation of the seed lift assembly) or keep the seed lift assembly in balance. Thus, the control signal can be generated such that it causes the moveable counterweight to offset a deviation (e.g., a sensed deviation or a predicted deviation) of the center of mass of the seed lift assembly from its axis of rotation.

At block 1114, the control signal can be used to drive a movable counterweight accordingly (e.g., to offset the deviation). Driving the movable counterweight at block 1114 can include actuating the counterweight driver to cause the movable counterweight to move towards a desired location. In some cases, driving the movable counterweight at block 1114 can include moving the movable counterweight at speed provided in the control signal. In some cases, driving the movable counterweight at block 1114 can include moving the movable counterweight for a duration equal to the duration of the control signal or a duration provided in the control signal.

Due to the dynamic adjustment of the movable counterweight at block 1108, deviations of the center of mass of the seed lift assembly from its axis of rotation can be corrected and/or avoided.

At a desired time, a desired length of ingot, a desired amount of material used, or based on other criteria, the process 1100 can end at block 1116.

While process 1100 is described with reference to certain blocks in certain orders, any suitable order can be used, along with additional and/or fewer blocks. For example, in some cases process 1100 further includes engaging a limit switch as part of or after lowering the seed crystal to the melt at block 1104.

The foregoing description of certain aspects of the present disclosure, including illustrated implementations, has been presented only for the purpose of illustration and description and is not intended to be exhaustive or limiting to the precise forms disclosed. Numerous modifications, adaptations, and uses thereof will be apparent to those skilled in the art. Numerous changes to the disclosed implementations can be made in accordance with the disclosure herein, without departing from the spirit or scope of the invention. Thus, the breadth and scope of the present invention should not be limited by any of the above described implementations.

Although the invention has been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular implementations only and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

As used below, any reference to a series of examples is to be understood as a reference to each of those examples disjunctively (e.g., “Examples 1-4” is to be understood as “Examples 1, 2, 3, or 4”).

Example 1 is a dynamic counterweight system for crystal growing, comprising: a counterweight assembly couplable to a seed lift assembly, the seed lift assembly being rotatably coupled to a receiving chamber about an axis of rotation and supporting a seed crystal within the receiving chamber, the counterweight assembly including: a movable counterweight that is axially movable between a first position and a second position along a counterweight axis; and a counterweight driver operably coupled to the movable counterweight to induce movement of the movable counterweight along the counterweight axis in response to a control signal; one or more sensors positioned to detect movement of the seed lift assembly; and a controller operably coupled to the one or more sensors and to the counterweight driver, the controller configured to: receive one or more sensor signals from the one or more sensors; generate the control signal based on the received one or more sensor signals; and transmit the control signal to the counterweight driver, wherein the control signal, when received by the counterweight driver, induces movement of the movable counterweight to offset deviations of a center of mass of the seed lift assembly.

Example 2 is the dynamic counterweight system of example(s) 1, wherein the one or more sensors includes a load cell positioned to couple the seed lift assembly to the receiving chamber to detect force applied to the receiving chamber by the seed lift assembly as the seed lift assembly rotates about the axis of rotation.

Example 3 is the dynamic counterweight system of example(s) 1 or 2, wherein the one or more sensors includes a load cell positioned between the receiving chamber and a furnace tank to detect force applied to the furnace tank by the receiving chamber as the seed lift assembly rotates about the axis of rotation.

Example 4 is the dynamic counterweight system of example(s) 1-3, wherein the one or more sensors includes an accelerometer positioned on the seed lift assembly to detect acceleration of the seed lift assembly during rotation of the seed lift assembly about the axis of rotation.

Example 5 is the dynamic counterweight system of example(s) 1-4, wherein the one or more sensors includes an accelerometer fixedly positioned with respect to the receiving chamber to detect acceleration of the receiving chamber during rotation of the seed lift assembly about the axis of rotation.

Example 6 is the dynamic counterweight system of example(s) 1-5, wherein the one or more sensors includes a rotational position sensor for detecting a rotational position of the seed lift assembly with respect to the receiving chamber.

Example 7 is the dynamic counterweight system of example(s) 1-6, wherein the counterweight driver includes a motor coupled to a leadscrew to rotate the leadscrew in response to the control signal, wherein the movable counterweight is coupled to the leadscrew, and wherein rotation of the leadscrew induces sliding of the movable counterweight along the counterweight axis.

Example 8 is the dynamic counterweight system of example(s) 1-7, wherein the seed lift assembly includes a spool having a helical collection groove extending along a length of the spool, wherein the spool is rotatable about a spool axis to wind a cable into the collection groove as the spool moves longitudinally along the spool axis, wherein the cable supports the seed crystal in the receiving chamber, and wherein the counterweight axis is parallel to the spool axis.

Example 9 is the dynamic counterweight system of example(s) 8, wherein at least some of the deviations of the center of mass of the seed lift assembly are caused by the longitudinal movement of the spool in a first direction during a crystal growing operation, and wherein the control signal, when received by the counterweight driver, induces the movable counterweight to move in a second direction that is opposite the first direction to offset the at least some of the deviations of the center of mass of the seed lift assembly.

Example 10 is a crystal growing system, comprising: a furnace tank having a crucible containing a melt; a receiving chamber having a lower end coupled to the furnace tank by an isolation valve and a top end coupled to a leveling adapter by a plurality of leveling adapter posts; a seed crystal suspended within the receiving chamber by a cable along a cable centerline; a seed lift assembly rotatably coupled to the receiving chamber about an axis of rotation via the leveling adapter and having an assembly center of mass along the cable centerline, the seed lift assembly supporting the cable within the growth chamber, the seed lift assembly having a spool for raising the cable, the spool having a spool center of mass that moves with respect to the cable centerline as the cable is raised; and a dynamic counterweight system, comprising: a counterweight assembly coupled to the seed lift assembly, the counterweight assembly including: a movable counterweight that is axially movable between a first position and a second position along a counterweight axis; and a counterweight driver operably coupled to the movable counterweight to induce movement of the movable counterweight along the counterweight axis in response to a control signal; one or more sensors positioned to detect movement of the seed lift assembly; and a controller operably coupled to the one or more sensors and to the counterweight driver, the controller configured to: receive one or more sensor signals from the one or more sensors; generate the control signal based on the received one or more sensor signals; and transmit the control signal to the counterweight driver, wherein the control signal, when received by the counterweight driver, induces movement of the movable counterweight to offset deviations of the assembly center of mass from the cable centerline, and wherein at least some of the deviations of the assembly center of mass from the cable centerline are caused by the movement of the spool center of mass as the cable is raised.

Example 11 is the crystal growing system of example(s) 10, wherein the one or more sensors includes a load cell positioned at one of the leveling adaptor posts to detect force applied to the receiving chamber by the seed lift assembly as the seed lift assembly rotates about the axis of rotation.

Example 12 is the crystal growing system of example(s) 10 or 11, wherein the one or more sensors includes a load cell positioned between the receiving chamber and the isolation valve to detect force applied to the furnace tank by the receiving chamber as the seed lift assembly rotates about the axis of rotation.

Example 13 is the crystal growing system of example(s) 10-12, wherein the one or more sensors includes an accelerometer positioned on the seed lift assembly to detect acceleration of the seed lift assembly during rotation of the seed lift assembly about the axis of rotation.

Example 14 is the crystal growing system of example(s) 10-13, wherein the one or more sensors includes an accelerometer positioned at the leveling adapter or at the isolation valve to detect acceleration of the receiving chamber during rotation of the seed lift assembly about the axis of rotation.

Example 15 is the crystal growing system of example(s) 10-14, wherein the one or more sensors includes a rotational position sensor for detecting a rotational position of the seed lift assembly with respect to the leveling adapter.

Example 16 is the crystal growing system of example(s) 10-15, wherein the counterweight driver includes a motor coupled to a leadscrew to rotate the leadscrew in response to the control signal, wherein the movable counterweight is coupled to the leadscrew, and wherein rotation of the leadscrew induces sliding of the movable counterweight along the counterweight axis.

Example 17 is the crystal growing system of example(s) 10-16, further comprising a limit switch assembly mechanically coupled to the spool to limit movement of the spool beyond one or more limit positions, wherein the limit switch assembly is not driven by the counterweight driver.

Example 18 is a method for growing a crystal, comprising: lowering a seed crystal to a melt by a cable supported by a seed lift assembly; simultaneously rotating the seed lift assembly about an axis of rotation and raising the cable, wherein raising the cable includes raising the cable via movement of a component of the seed lift assembly, wherein movement of the component causes a center of mass of the component to be moved with respect to the axis of rotation; and dynamically offsetting a deviation of an assembly center of mass of the seed lift assembly from the axis of rotation, wherein dynamically offsetting the deviation includes: detecting movement of the seed lift assembly during rotation of the seed lift assembly via one or more sensors; generating a control signal based on the detected movement; transmitting the control signal to a counterweight driver operably coupled to a movable counterweight that is axially movable between a first position and a second position along a counterweight axis; and driving the movable counterweight by the counterweight driver in response to receiving the transmitted control signal, wherein driving the movable counterweight includes inducing movement of the movable counterweight by an amount sufficient to offset the deviation.

Example 19 is the method of example(s) 18, wherein the seed lift assembly is coupled to a receiving chamber by a leveling adaptor, the leveling adaptor being coupled to the receiving chamber by a plurality of leveling adapter posts; wherein the melt is contained within a furnace tank coupled to the receiving chamber by an isolation valve; and wherein detecting movement of the seed lift assembly during rotation of the seed lift assembly via one or more sensors includes: i) detecting force applied to the receiving chamber by the seed lift assembly via a load cell positioned at one of the leveling adaptor posts of the leveling adapter; ii) detecting force applied to the furnace tank by the receiving chamber via a load cell positioned between the receiving chamber and the isolation valve; iii) detecting acceleration of the seed lift assembly via an accelerometer positioned on the seed lift assembly; iv) detecting acceleration of the receiving chamber via an accelerometer positioned at the leveling adapter; v) detecting acceleration of the receiving chamber via an accelerometer positioned at the isolation valve; vi) detecting rotational position of the seed lift assembly with respect to the leveling adapter; or vii) any combination of i-vi.

Example 20 is the method of example(s) 18 or 19, wherein the counterweight driver includes a motor coupled to a leadscrew to rotate the leadscrew in response to the control signal, wherein the movable counterweight is coupled to the leadscrew, and wherein rotation of the leadscrew induces sliding of the movable counterweight along the counterweight axis.

What is claimed is:

1. A dynamic counterweight system for crystal growing, comprising:
a counterweight assembly couplable to a seed lift assembly, the seed lift assembly being rotatably coupled to a receiving chamber about an axis of rotation and supporting a seed crystal within the receiving chamber, the counterweight assembly including:
a movable counterweight that is axially movable between a first position and a second position along a counterweight axis; and
a counterweight driver operably coupled to the movable counterweight to induce movement of the movable counterweight along the counterweight axis in response to a control signal;
one or more sensors positioned to detect movement of the seed lift assembly; and
a controller operably coupled to the one or more sensors and to the counterweight driver, the controller configured to:
receive one or more sensor signals from the one or more sensors;
generate the control signal based on the received one or more sensor signals; and
transmit the control signal to the counterweight driver, wherein the control signal, when received by the counterweight driver, induces movement of the movable counterweight to offset deviations of a center of mass of the seed lift assembly.

2. The dynamic counterweight system of claim 1, wherein the one or more sensors includes a load cell positioned to couple the seed lift assembly to the receiving chamber to detect force applied to the receiving chamber by the seed lift assembly as the seed lift assembly rotates about the axis of rotation.

3. The dynamic counterweight system of claim 1, wherein the one or more sensors includes a load cell positioned between the receiving chamber and a furnace tank to detect force applied to the furnace tank by the receiving chamber as the seed lift assembly rotates about the axis of rotation.

4. The dynamic counterweight system of claim 1, wherein the one or more sensors includes an accelerometer positioned on the seed lift assembly to detect acceleration of the seed lift assembly during rotation of the seed lift assembly about the axis of rotation.

5. The dynamic counterweight system of claim 1, wherein the one or more sensors includes an accelerometer fixedly positioned with respect to the receiving chamber to detect acceleration of the receiving chamber during rotation of the seed lift assembly about the axis of rotation.

6. The dynamic counterweight system of claim 1, wherein the one or more sensors includes a rotational position sensor for detecting a rotational position of the seed lift assembly with respect to the receiving chamber.

7. The dynamic counterweight system of claim 1, wherein the counterweight driver includes a motor coupled to a leadscrew to rotate the leadscrew in response to the control signal, wherein the movable counterweight is coupled to the leadscrew, and wherein rotation of the leadscrew induces sliding of the movable counterweight along the counterweight axis.

8. The dynamic counterweight system of claim 1, wherein the seed lift assembly includes a spool having a helical collection groove extending along a length of the spool, wherein the spool is rotatable about a spool axis to wind a cable into the collection groove as the spool moves longitudinally along the spool axis, wherein the cable supports the seed crystal in the receiving chamber, and wherein the counterweight axis is parallel to the spool axis.

9. The dynamic counterweight system of claim 8, wherein at least some of the deviations of the center of mass of the seed lift assembly are caused by the longitudinal movement of the spool in a first direction during a crystal growing operation, and wherein the control signal, when received by the counterweight driver, induces the movable counterweight to move in a second direction that is opposite the first direction to offset the at least some of the deviations of the center of mass of the seed lift assembly.

10. A crystal growing system, comprising:
a furnace tank having a crucible containing a melt;
a receiving chamber having a lower end coupled to the furnace tank by an isolation valve and a top end coupled to a leveling adapter by a plurality of leveling adapter posts;
a seed crystal suspended within the receiving chamber by a cable along a cable centerline;
a seed lift assembly rotatably coupled to the receiving chamber about an axis of rotation via the leveling adapter and having an assembly center of mass along the cable centerline, the seed lift assembly supporting the cable within the growth chamber, the seed lift assembly having a spool for raising the cable, the spool having a spool center of mass that moves with respect to the cable centerline as the cable is raised; and
a dynamic counterweight system, comprising:
a counterweight assembly coupled to the seed lift assembly, the counterweight assembly including:
a movable counterweight that is axially movable between a first position and a second position along a counterweight axis; and
a counterweight driver operably coupled to the movable counterweight to induce movement of the movable counterweight along the counterweight axis in response to a control signal;
one or more sensors positioned to detect movement of the seed lift assembly; and
a controller operably coupled to the one or more sensors and to the counterweight driver, the controller configured to:
receive one or more sensor signals from the one or more sensors;
generate the control signal based on the received one or more sensor signals; and
transmit the control signal to the counterweight driver, wherein the control signal, when received by the counterweight driver, induces movement of the movable counterweight to offset deviations of the assembly center of mass from the cable centerline, and wherein at least some of the deviations of the assembly center of mass from the cable centerline are caused by the movement of the spool center of mass as the cable is raised.

11. The crystal growing system of claim 10, wherein the one or more sensors includes a load cell positioned at one of the leveling adaptor posts to detect force applied to the receiving chamber by the seed lift assembly as the seed lift assembly rotates about the axis of rotation.

12. The crystal growing system of claim 10, wherein the one or more sensors includes a load cell positioned between the receiving chamber and the isolation valve to detect force applied to the furnace tank by the receiving chamber as the seed lift assembly rotates about the axis of rotation.

13. The crystal growing system of claim 10, wherein the one or more sensors includes an accelerometer positioned on the seed lift assembly to detect acceleration of the seed lift assembly during rotation of the seed lift assembly about the axis of rotation.

14. The crystal growing system of claim 10, wherein the one or more sensors includes an accelerometer positioned at the leveling adapter or at the isolation valve to detect acceleration of the receiving chamber during rotation of the seed lift assembly about the axis of rotation.

15. The crystal growing system of claim 10, wherein the one or more sensors includes a rotational position sensor for detecting a rotational position of the seed lift assembly with respect to the leveling adapter.

16. The crystal growing system of claim 10, wherein the counterweight driver includes a motor coupled to a leadscrew to rotate the leadscrew in response to the control signal, wherein the movable counterweight is coupled to the leadscrew, and wherein rotation of the leadscrew induces sliding of the movable counterweight along the counterweight axis.

17. The crystal growing system of claim 10, further comprising a limit switch assembly mechanically coupled to the spool to limit movement of the spool beyond one or more limit positions, wherein the limit switch assembly is not driven by the counterweight driver.

18. A method for growing a crystal, comprising:
lowering a seed crystal to a melt by a cable supported by a seed lift assembly;
simultaneously rotating the seed lift assembly about an axis of rotation and raising the cable, wherein raising the cable includes raising the cable via movement of a component of the seed lift assembly, wherein movement of the component causes a center of mass of the component to be moved with respect to the axis of rotation; and
dynamically offsetting a deviation of an assembly center of mass of the seed lift assembly from the axis of rotation, wherein dynamically offsetting the deviation includes:
detecting movement of the seed lift assembly during rotation of the seed lift assembly via one or more sensors;
generating a control signal based on the detected movement;
transmitting the control signal to a counterweight driver operably coupled to a movable counterweight that is axially movable between a first position and a second position along a counterweight axis; and
driving the movable counterweight by the counterweight driver in response to receiving the transmitted control signal, wherein driving the movable counterweight includes inducing movement of the movable counterweight by an amount sufficient to offset the deviation.

19. The method of claim 18, wherein the seed lift assembly is coupled to a receiving chamber by a leveling adaptor, the leveling adaptor being coupled to the receiving chamber by a plurality of leveling adapter posts; wherein the melt is contained within a furnace tank coupled to the receiving chamber by an isolation valve; and wherein detecting movement of the seed lift assembly during rotation of the seed lift assembly via one or more sensors includes:
i) detecting force applied to the receiving chamber by the seed lift assembly via a load cell positioned at one of the leveling adaptor posts of the leveling adapter;
ii) detecting force applied to the furnace tank by the receiving chamber via a load cell positioned between the receiving chamber and the isolation valve;
iii) detecting acceleration of the seed lift assembly via an accelerometer positioned on the seed lift assembly;
iv) detecting acceleration of the receiving chamber via an accelerometer positioned at the leveling adapter;
v) detecting acceleration of the receiving chamber via an accelerometer positioned at the isolation valve;
vi) detecting rotational position of the seed lift assembly with respect to the leveling adapter; or
vii) any combination of i-vi.

20. The method of claim 18, wherein the counterweight driver includes a motor coupled to a leadscrew to rotate the leadscrew in response to the control signal, wherein the movable counterweight is coupled to the leadscrew, and wherein rotation of the leadscrew induces sliding of the movable counterweight along the counterweight axis.
